(19) United States
(12) Patent Application Publication
(10) Pub. No.: US 2005/0280990 A1
(43) Pub. Date: Dec. 22, 2005

(54) Fan module

(76) Inventors: Ryan K. Goodenough, Marlton, NJ (US); Thomas J. Carullo, Marlton, NJ (US)

Correspondence Address: BECK AND TYSVER P.L.L.C., 2900 THOMAS AVENUE SOUTH, SUITE 100, MINNEAPOLIS, MN, 55416, US

(21) Appl. No.: 10/873,339

(22) Filed: Jun. 21, 2004

(51) Int. Cl. H05K 1/00

(52) U.S. Cl. 361/695; 165/80.3

(57) ABSTRACT

A fan module includes a shell molded from plastic in a unitary construction. In the shell is mounted one or more fans, a printed circuit board assembly and a latching member.

### FIELD OF THE INVENTION

The present invention relates generally to a fan module and more particularly to a fan module for snap-in mounting to a chassis for housing electrical circuitry. Further, operational components snap into a shell to form the fan module.

### BACKGROUND OF THE INVENTION

Electrical circuitry residing in a chassis or housing typically generates heat and therefore requires cooling to perform properly. This cooling is typically accomplished throughfans drawing cooler environmental air through the chassis or exhausting the chassis's internal warm air to the environment. It is common for such fans to burn out or require service on a periodic basis during the life of the circuitry in the chassis. Fan burn out is problematic for at least a couple of reasons. First, when a fan's performance is compromised, it does not cool the circuitry and therefore the circuitry may overheat and fail. Second, changing a fan typically requires that the circuitry be shut down while the chassis is opened and the fans replaced. This is typically slow and detrimental to the operations that rely upon the circuitry.

Still another issue with fans for circuitry has been that it is important that the fans provide some indication that they have ceased to operate or are operating at less than full capacity.

Yet another issue with fans for circuitry is making the installation of the fans simple both for in-the-field replacement, but also for original manufacture. Typically, screws and other extraneous hardware are required to install the fans, and it is time-consuming to connect such hardware, both during original manufacture and in-the-field. Further, for manufacture, such hardware must be stocked and its inventory tracked, thereby adding to the cost of goods sold.

Giraldo, U.S. Pat. No. 6,616,525 describes fan modules that assist in making the replacement of fans easier or quicker. Specifically, Giraldo describes hot swappable fan modules that reside on the exterior of the chassis so that they can be replaced without opening the chassis. Further, Giraldo describes modules with a mounting configuration that allows a fan module to be installed on a chassis without additional hardware.

There has not yet been a fan module that overcomes all of the above-mentioned challenges to provide an easily manufactured, easily installable fan module.

### SUMMARY OF THE INVENTION

The present invention provides a fan module that easily mounts to the outside of a chassis housing electrical circuitry. The module includes a shell that houses one or more fans and a printed circuit board.

The shell is molded from plastic as a single, unitary member. Molded into the shell are features, such as resilient tangs terminating in latching protrusions, that allow a fan to snap-couple to the shell, without requiring any extraneous hardware to assembly the fan in the shell. Also molded into the shell are locating protrusions which cooperate with recesses in a fan flange that are typically provided in off-the-shelf fans for receiving screws, to allow the fan to be properly positioned within the shell.

Further features are molded into the shell and support a printed circuit board (PCB) assembly that carries circuits to monitor the status (specifically, the rotational speed) of the fans and to power the fans. The shell defines slots or grooves to support opposite edges of a PCB. Stopping protrusions at the terminating end of resilient tangs hold the PCB when the PCB is fully installed in the slots. By cooperation of the slots and the stopping protrusions on the tangs, the printed circuit board assembly is mounted in the shell without any additional or extraneous hardware. The PCB-supporting features in the shell allow some play in the position of the PCB to allow use of an off the shelf board-to-board connector set to achieve a blind mate with a connector on the chassis.

The molded shell provides channels for guiding wires from the fans to the printed circuit board assembly.

Still further, molded into the shell are features that enhance the aerodynamic performance of the fans. Specifically, a grill covering that is adjacent the fan bears rounded edges immediately adjacent the fan to reduce turbulence due to the air moved by the fan hitting the grill covering. Such refined shaping is accomplished due the molded nature of the shell.

The printed circuit board assembly supported in the shell contains connectors for electrical coupling to the fans to provide power from a power source to which the PCB is connected and to receive electronic data from the fans as to their rotational speed.

### BRIEF DESCRIPTION OF THE DRAWINGS

An exemplary version of a fan module is shown in the figures wherein like reference numerals refer to equivalent structure throughout, and wherein:

FIG. 1 is a perspective view of fan module according to the present invention, viewed generally from the front;

FIG. 2 is a perspective view of the fan module of FIG. 1, viewed generally from the rear;

FIG. 3 is a perspective view of the fan module of FIG. 1, viewed generally from the lower rear;

FIG. 4 is an exploded perspective view of a chassis housing electrical circuitry, with the chassis' components include three fan modules like those of FIG. 1;

FIG. 5 is a perspective view, viewed generally from the front, of a shell of a fan module, empty of operational components except for a latching member;

FIG. 6 is a perspective view of the shell of FIG. 5, viewed generally from the rear;

FIG. 7 is a perspective view of the shell of FIG. 7, viewed generally from the bottom rear;

FIG. 8 is a front view of the shell of FIG. 5;

FIG. 9 is a perspective view of the shell of FIG. 5;

FIG. 10 is an enlarged perspective view of a portion of the shell of FIG. 5, showing a resilient tang for snap-coupling a fan to the shell;

FIG. 11 is an enlarged perspective view of a portion of the shell of FIG. 5, showing a resilient tang for engaging a printed circuit board assembly in the shell;

FIG. 12 is an enlarged side view of a portion of the shell of FIG. 5, showing the slot and tang cooperation to engage a printed circuit board assembly in the shell;

FIG. 13 is an enlarged perspective view of a latching member that is part of the fan module of FIG. 1;

FIG. 14 is a greatly enlarged side view of the latching member of FIG. 13 installed in a shell of FIG. 5 and mounted in a chassis;

FIG. 15 is an end view of the latching member of FIG. 13;

FIG. 16 is a top view of a printed circuit board that is part of a fan module depicted in FIG. 1;

FIG. 17 is a side, cross-section view of a portion of the shell of FIG. 5;

FIG. 18 is a side view of the shell of FIG. 5;

FIG. 19 is a top view of the shell of FIG. 5;

FIG. 20a is a front view of a commercially-available, off-the-shelf fan for incorporating into a fan module of FIG. 1; and

FIG. 20b is a side view of the fan of FIG. 20a.

### DETAILED DESCRIPTION OF PREFERRED EMBODIMENT(S)

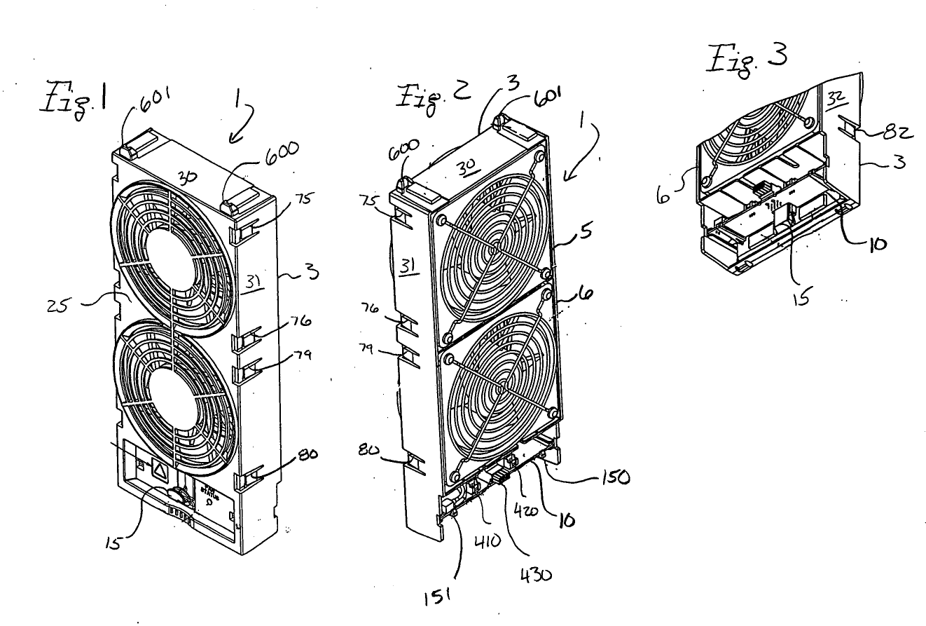

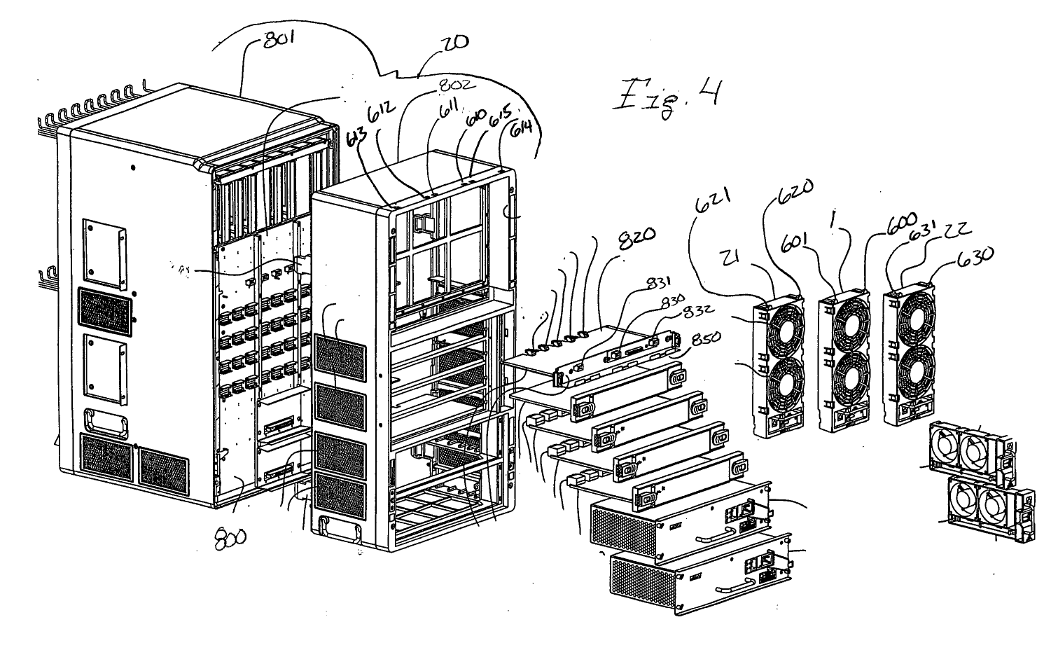

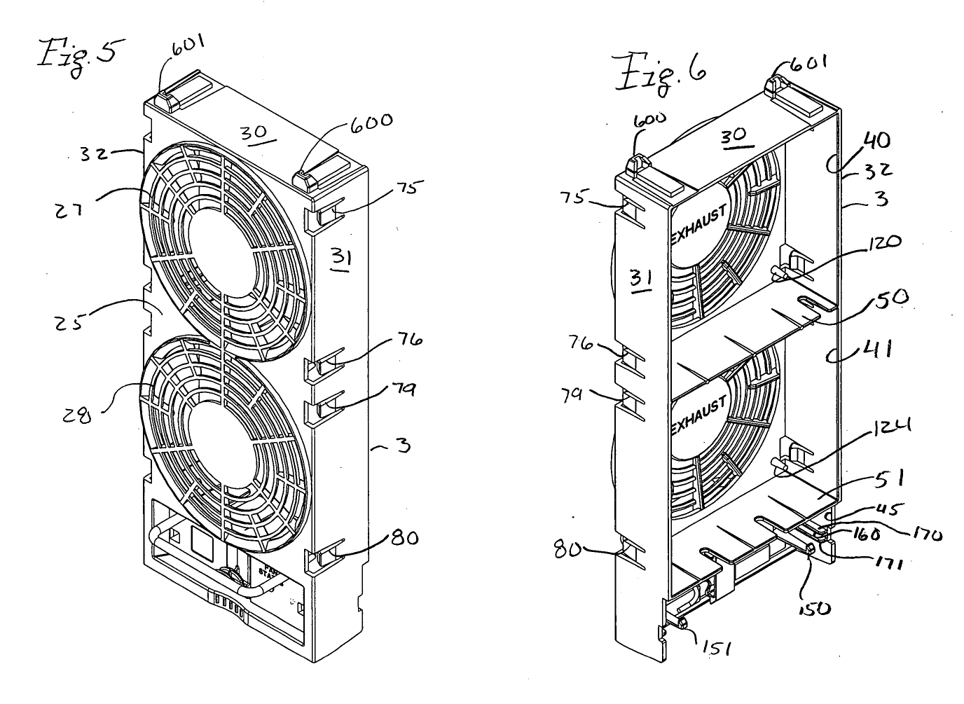

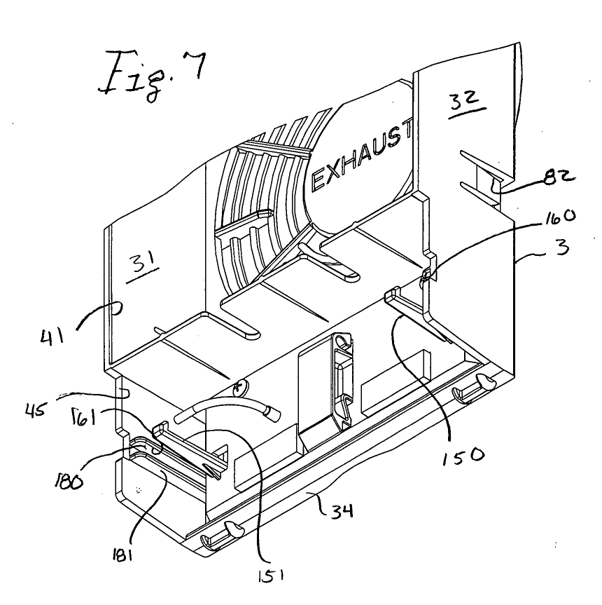

FIGS. 1 and 2 show a preferred embodiment of a fan module 1. The fan module 1 includes a shell 3 that is molded of plastic as a single unitary body. The shell 3 houses or supports operational components of the fan module 1. These components include individual conventional off-the-shelf fan(s) 5, 6 (more visible in FIG. 2), a printed circuit board assembly 10 (FIG. 2) and a latching member 15 (FIG. 1). As depicted in FIG. 4, the fan module 1 mounts on a chassis 20 that houses electrical circuitry and the fans 5, 6 of the fan module 1 cool the circuitry in the chassis 20. FIG. 4 shows an example of such a chassis 20 with three fan modules 1, 21, 22. The manner in which the fan modules 1, 21, 22 are mounted and secured to a chassis 20 will be discussed below.

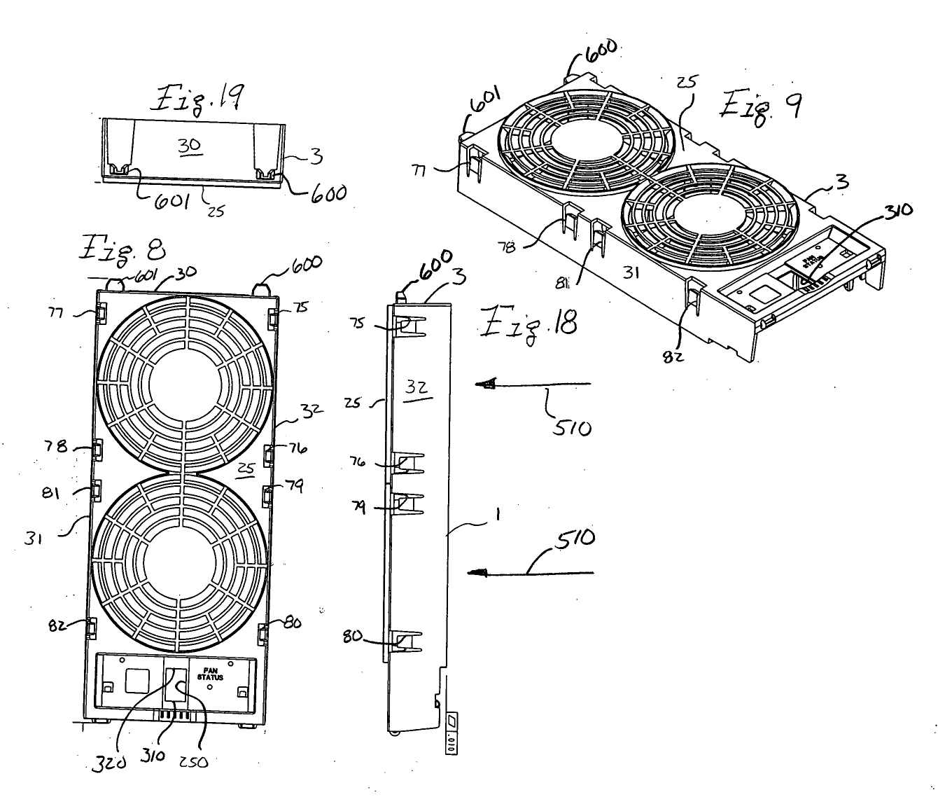

Molded into the shell 3 are various features that allow the operational components of the fan module 1 to be mounted and secured in the shell 3 without any extraneous hardware, providing for relatively quick and cheap assembly during manufacture and service. The shell 3 illustrated throughout the figures includes compartments for two individual fans, but it will be understood that the shell 3 may be adapted to accommodate one or more than two fans. FIGS. 1-3 illustrate the shell 3 with components mounted therein. FIGS. 8 and 9 illustrate the shell 3 without the components mounted therein; FIGS. 5-7 illustrate the shell 3 without the fans and without the printed circuit board, but including the latching member 15.

With reference to FIGS. 5 and 6, the shell 3 has a front face 25 that defines two grill areas 27, 28 that allow air moved by the fans 5, 6 to pass therethrough. Generally perpendicular to the front face 25 extend a top wall 30 and side walls 31 and 32. A bottom wall 34 similarly extends from the front face generally perpendicular thereto, as shown in FIG. 7. The shell 3 is essentially backless.

The shell 3 defines compartments 40, 41 (FIG. 6), each for receiving one individual fan 5, 6 (FIG. 2). Further, the shell 3 defines a compartment 45 (FIGS. 6 and 7) for receiving and supporting a printed circuit board assembly 10. As shown in FIG. 6, the compartment 40 for housing a first fan is generally bounded by the top wall 30, portions of side walls 31, 32 and by a baffle 50 that extends betweens walls 31 and 32 generally parallel to the top wall 30. The second compartment 41 is bounded by the baffle 50, portions of side walls 31, 32 and a second baffle 51.

The features involved in the mounting and securing of the individual fans will be understood with reference to FIG. 6. Molded into the shell 3 are resilient tangs 75-82. The tangs 75-82 are positioned roughly adjacent the corners of the fan compartments 40, 41. More specifically, tangs 75-78 are positioned roughly adjacent the corners of the fan compartment 40; tangs 79-82 are positioned roughly adjacent the corners of the fan compartment 41. FIG. 10 shows an enlarged view of a representative tang 81. As noted above, the tang 81 is molded as part of the shell 3 and therefore in integral with the surrounding shell material; for tang 81, the surrounding shell material is side wall 32. An aperture 90 in the wall 32 (that further extends into front face 25) surrounds the tang 81, such that it is a peninsula of plastic material projecting from the contiguous land of the side wall 32 into the sea of the aperture 90. Because of the elastic properties of the plastic material forming the shell 3, the tang is resilient and can wiggle to some degree with respect of the wall 32. The tang 81 terminates in a latch protrusion 95 that extends inwardly into the compartment 41 further than the adjacent, contiguous body portion 96 of the tang 81. The terminating end of the latch protrusion has a sloped or slanted surface 100. In use, as a fan is inserted into the compartment 41, the slanted surface 100 of the tang 81 (and analogous structure on the other tangs 79, 80, 82) engages the flange of the fan. As the flange advances into the compartment, the tang 81 is pushed outwardly (to the exterior of the shell 3) until the terminating edge 102 of the tang 81 clears the flange. Having cleared the flange, the tang 81 resiliently bounces back and the flange is sandwiched between the front face 25 of the shell and the lower surface 103 of the tang. In this manner, a fan can be snapped into the shell 3 and is secured and retained there without the use of any extraneous hardware such as screws or the like. The lower surface 103 of the tang 81 is slanted or sloped as well and therefore, when desired, the fan can be pulled out of the shell. When removing the fan, the fan flange contacts the sloped lower surface 103 of the tang 81 and pushed the tang outward until the flange clears the terminating edge 102.

As further illustrated in FIG. 6, each compartment 40, 41 includes locating protrusions 120, 124. Preferably, there are four such protrusions within each compartment and they are located roughly adjacent the four corners of the compartments. Only two representative protrusions 120, 124 are apparent in FIG. 6. These locating protrusions extend into the compartments 40, 41 from the interior side of the front face 25. These protrusions 120, 124 are positioned to mate with standard hole geometry in an off-the shelf fan. Typically, such holes are used for receiving screws or the like to mount the fan. However, since no such hardware is required in the module 1 of the present invention, these holes can be put to use in another task. These protrusions 120, 124 assure that the fan is properly positioned within the compartment 40, 41.

FIGS. 6 and 7, in conjunction with FIGS. 2 and 3, illustrate the features molded into the shell 3 that mount and secure a printed circuit board assembly 10 in the shell 3. As noted above, FIGS. 6 and 7 show the shell 3 without the printed circuit board assembly 10 installed, while FIGS. 2 and 3 show the assembly 10 installed in the shell 3. The printed circuit board assembly 10 is mounted in the shell 3 via coordinating resilient tangs 150, 151 and slots 160, 161. Tangs 150, 151 and slot 160 are visible in FIG. 6; tangs 150, 151 and slot 161 are visible in FIG. 7. Each slot 160, 161 is defined by two generally planar protrusions extending inwardly from the side walls 31, 32 of the shell 3 and parallel to one another. As shown in FIG. 6, planar protrusions 170 and 171 define slot 160; as shown in FIG. 7, planar protrusions 180, 181 define slot 161. The protrusions within a cooperating pair (170 paired with 171; 180 paired with 181) are spaced apart a distance sufficient to accommodate the edges of a printed circuit board assembly therebetween. Sizes and tolerances allow some play between the printed circuit board assembly and the shell. Similarly, the slot 160 is spaced from slot 161 a distance sufficient to accommodate the width of a printed circuit board assembly 10 (FIGS. 2 and 3).

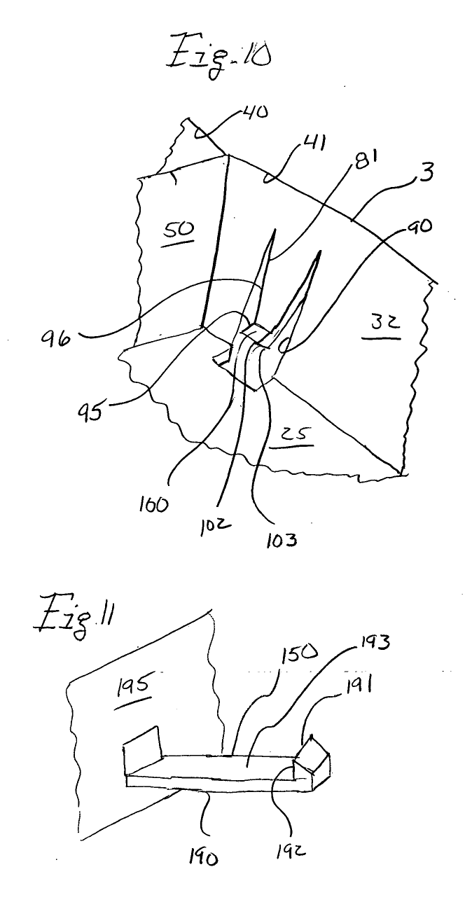

The resilient tangs 150, 151 extend from the interior of the front face 25 and extend generally parallel to the slots 160, 161. An enlarged representative tang 150 is illustrated in FIG. 11. The tang 150 has a generally elongate body 190 and terminates in a stopping protrusion 191 that has a face 192 that is generally perpendicular to the upper surface 193 elongate body 190. Because the tangs 150, 151 are integrally molded as part of the shell 3, the tangs 150, 151 are integral with the surrounding shell material. Surrounding shell material is represented by reference number 195 in FIG. 11. The tangs 150, 151 are resilient as a result of the elasticity of the plastic material from which the shell is molded.

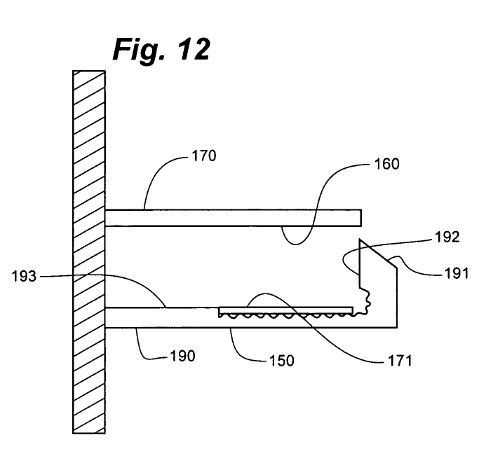

FIG. 12 illustrates the positioning of a representative tang 150 in relation to a representative slot 160. Generally, the upper surface 193 of the tang body 190 is co-planar with the upper surface of the planar protrusion 171, the lower of the two protrusions 170, 171 that defines the slot 160. The face 192 of the stopping protrusion 191 is roughly aligned with the end or edge of the planar protrusions 171. Sizes and tolerances provide for some play between the printed circuit board assembly and the shell.

As will be appreciated with reference to FIGS. 2 and 3, to install a printed circuit board assembly 10, the edges of the board are inserted into slots 160, 161. The board deflects the tangs 150, 151 downward so that the board clears the stopping protrusions 191. When the back edge of the printed circuit board clears the stopping protrusion 191, the tangs 150, 151 pop upward with the stopping protrusion securing the board assembly 10 in the shell 10. Of course, by selectively moving the tangs 150, 151 downward, the printed circuit board assembly 10 can be removed when so desired.

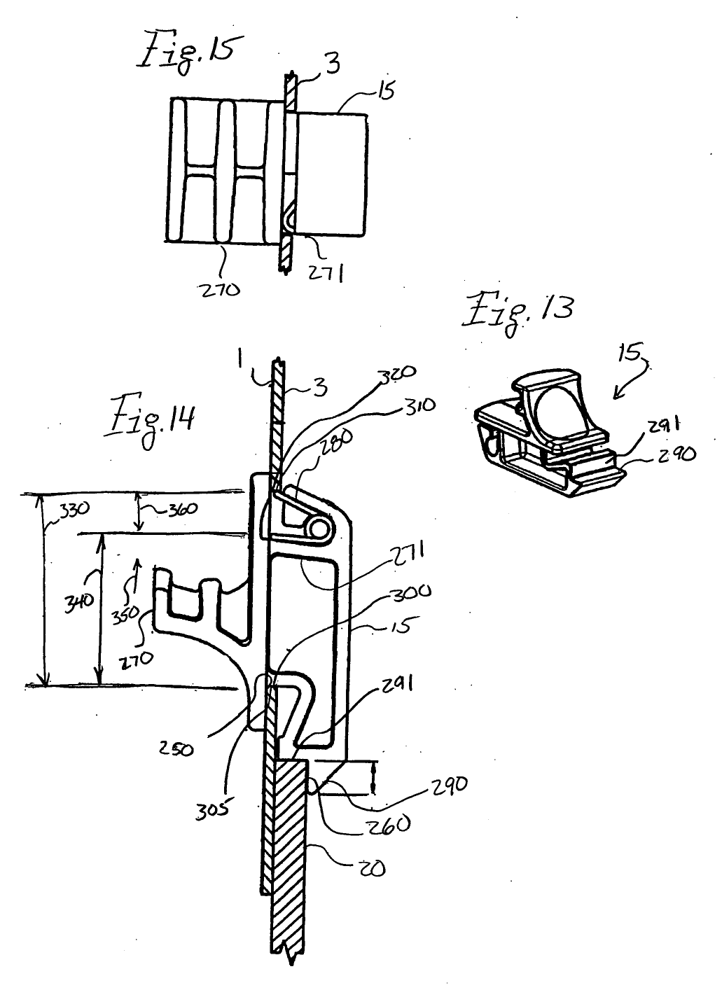

Another component of the fan module 1 is the latching member or latch 15, shown in FIGS. 1 and 13-15. The latch member 15 is preferably a sliding member that engages a lip or stop on the chassis to which the fan module 1 is mounted. In a preferred embodiment, the latching member 15 is a self-contained element, as illustrated in FIG. 13. The latching member 15 is received in an aperture 250 defined in the shell 3 to attach the latching member 15 to the shell 3. This aperture 250 is apparent in FIG. 8. FIG. 14 illustrates the latching member 15, installed in a shell 3 and in engagement with a lip or stop 260 on the chassis 20. The latching member 15 has a handle portion 270 attached to a body 271. The latching member 15 includes a spring 280 which interacts with the shell 3 to bias the latching member 15 in a preferred position with respect to the shell 3. The latching member 15 further includes a catch protrusion 290 extending from the body 271 of the latching member 15. The catch protrusion 290 extends generally perpendicularly to an adjacent stopping surface 291 of the latch body 291. Portions of the latching member 15, when installed in a shell 3, abut the edges of the aperture 250 in which the latching member 15 resides. More specifically, surface 300 abuts the shell 3 (specifically, an edge 305 of the aperture 250) when the latch member 15 is in the position urged by the bias of the spring 280. A portion 310 of the spring 280 abuts the opposite edge 320 of the aperture 250 in the shell 3.

Two relative dimensions are indicated in FIG. 14 and these dimensions facilitate the operation of the latching member 15. Relative dimension 330 represents the distance between opposite edges 305 and 320 of the aperture 250. Relative dimension 340 represents the dimension of the body 271 of the latching member 15, at the section of the body 271 that resides within the aperture 250, when the spring 280 is fully compressed.

In its spring-biased position, illustrated in FIG. 14, the latching member 15 resides with its stopping surface 291 abutting the lip 260 of the chassis 20, and with its surface 300 abutting the edge 305 of the aperture 250 in the shell 3. To disengage the latching member 15, and hence to remove the fan module from the chassis, the user applies force to the handle, in the direction indicated by arrow 350. Force in direction 350 causes the spring 280 to compress. The latching member 15 slides within the aperture 250 from a first position, illustrated in FIG. 14, to a second position, displaced a distance 360 from its starting position in the direction 350. This travel allows the catch protrusion 290 to clear the lip 260 of the chassis 20, thereby freeing the latch 15, and hence the fan module 1, from the chassis 20.

The printed circuit board assembly 10 for a two-fan module 1 is illustrated in FIG. 16. The preferred assembly includes a printed circuit board 400. Electrically coupled to the board 400 are two connectors 410, 420, one each for electrical connection to a fan. The fans are hard-wired to these connectors 410, 420 and the connectors provide both data and power transfer between the assembly 10 and the fans via hard wires. The printed circuit board assembly 10 further includes a connector 430 (that is electrically linked to connectors 410, 420 via the printed circuit board 400) for electrical connection to other components in the system housed by the chassis. One such other component is a power supply. Thus, power from the power supply is provided to the fans via connector 430, the printed circuit board 400, and connectors 410, 420 which in turn are hard-wired to the fans. Similarly, the system housed by the chassis monitors the status (such as the rotational speed) of the fans through transport of data from the fans, through connectors 410, 420, through printed circuit board 400, through connector 430 to the system in the chassis.

To guard against the failure of the fans (and subsequent overheating of the system cooled by the fans), it is preferred that the fans be linked to at least two power sources. An “or'ing” diode 450, electrically linked to the printed circuit board 400 and in turn to the fans, switches from a primary power source to a second, redundant power source upon failure of the primary source.

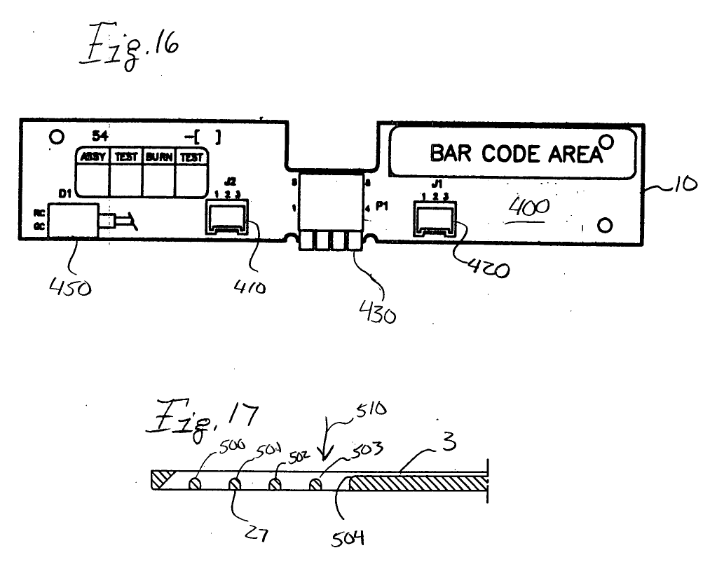

FIG. 17 illustrates an aerodynamic feature of the shell 3. The grill 27 (pictured in cross section, with only half of the grill 27 shown) presents rounded, smooth surfaces 500, 501, 502, 503, 504 to the air flow, passing in the direction indicated by arrow 510, through the fans. These rounded, smooth surface are easily manufactured during the molding process to manufacture the shell 3. FIG. 18 illustrates a side view of the fan module 1, with fans oriented to exhaust air from the interior of a chassis. The rounded, smooth surfaces 500-504 are thus located on the interior of the shell 3.

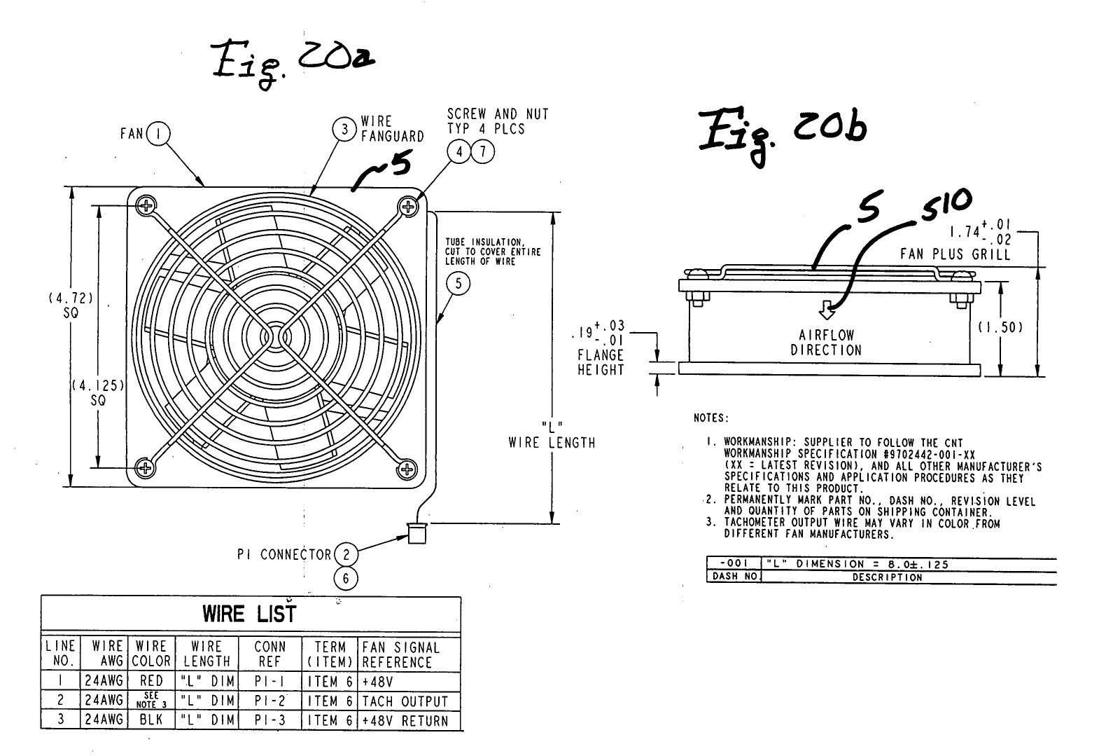

As noted above with reference to FIG. 4, the fan module 1 (and like fan modules 21, 22) mount to a chassis 20. This coupling is accomplished in part by the sliding latching member 15 as described above. In addition, the preferred fan module 1 includes additional features that cooperate with the chassis and these features will be described with respect to FIGS. 8, 18, 19 and 4. Specifically, tabs 600, 601 extend externally from the shell wall 30. These tabs 600, 601 are preferably rigid or not resilient. These tabs are sized and shaped to be received by mating recesses 610, 611 defined in the chassis 20, as shown in FIG. 4. Chassis 20 includes three pairs of such recesses (610 and 611; 612 and 613; 614 and 615), to receive tabs (600 and 601; 620 and 621; 630 and 631), respectively, from three fan modules 1, 21, 22. These tabs 610, 611, 620, 621, 630, 631 properly position the fan modules 1, 21, 22 in the chassis 20 in predetermined locations. Further, because the tabs 610, 611, 620, 621, 630, 631 extend into the mating apertures 610-615, respectively, the tabs help to retain the fan module 1, 21, 22 in the chassis 20 in conjunction with the engagement of the latching member 15 on the chassis 20 as described above.

The pictured example chassis 20 of FIG. 4 is divided along a midplane printed circuit board assembly 800 into front 801 and rear 802 sections. The pictured chassis 20 is described in greater detail in U.S. Ser. No. ______, filed Jun. 21, 2004, entitled “Modular Chassis Divided Along a Midplane and Cooling System Therefor” and is incorporated herein by reference. Features of the fan module 1 discussed herein are well-suited to coordinate with the midplane arrangement of the chassis 20, but it will be understood that the fan module 1 of the present invention and the shell 3 of this fan module 1 may be used in conjunction with other types of chassis designs. To coodinate with the midplane 800, the printed circuit board assembly 10 of each fan module 1, 21, 22 connects to another printed circuit board assembly 820 via connectors typified by connector 430 in module 1 and via mating connectors 830, 831, 832. When a fan module 1 is installed in the chassis, the module connector 430 blind-mates with connector 830, thereby establishing an electrical coupling between the fan module 1 and the printed circuit board assembly 820 which in turn is electrically coupled to the midplane 800. In the embodiment illustrated, a bracket 850 is mechanically coupled to the printed circuit board assembly 820 and this bracket 850 includes the lip 260 of the chassis to which the latching member 15 of the module 1 attaches, as described above with respect to FIG. 14.

The shell 3 is preferably molded from a PC-ABS material that complies with flame resistance standards (e.g. UL-94-VO flame resistance standard). Further the shell material preferably meets relevant environmental standards (e.g. European environmental Waste Electrical and Electronic Equipment standards, according to European Union Direction #2002/96/EC). Further, the shell housing preferably meets standards for polymer materials used in electrical equipment (e.g. UL 746).

FIGS. 20a and 20b show a commercially-available, off-the-shelf fan 5.

All directional words, such as “top”, “bottom”, “front”, “rear”, “rearward”, “upper” and “lower” and the like are used to reflect the orientation of the fan module 1 illustrated in the figures and do not have any substantive meaning. Such words are not intended to have limiting effect.

Although an illustrative version of the device is shown, it should be clear that many modifications to the device may be made without departing from the scope of the invention.

1. A shell for housing a fan, comprising:
a) means for snap-coupling a first fan to said shell;
b) means for snap-coupling a printed circuit board to said shell; and
c) said shell, including said fan snap-coupling means and said printed circuit board snap-coupling means, being molded of plastic and being a single member.

2. A shell according to claim 1, further comprising:
d) means for coupling a latch to the shell.

3. A shell according to claim 1, further comprising:
d) means for snap-coupling a second fan to said shell.

4. A shell according to claim 1, wherein said fan snap-coupling means includes resilient tangs, each tang terminating in a latching protrusion adapted to engage a fan flange, said tangs being formed as part of the unitary, molded construction of the shell.

5. A shell according to claim 4, wherein said fan snap-coupling means includes four resilient tangs, each tang terminating in a latching protrusion adapted to engage a fan flange, said tangs being positioned to engage a fan flange adjacent the four corners of a fan flange.

6. A shell according to claim 1, wherein said printed circuit board snap-coupling means includes resilient tangs, each tang terminating in a stopping protrusion, said tangs being sized such that the stopping protrusions engage an edge of the printed circuit board.

7. A shell according to claim 6, wherein said shell defines slots for receiving opposite edges of a printed circuit board, said slots being sized to receive an edge of a printed circuit board and said slots being positioned to cooperate with said tangs, such that a printed circuit board, when lodged in said shell, is supported by said slots and is maintained in place by said stopping protrusions.

8. A shell according to claim 7, wherein said slots are sized and positioned to allow some play in the position of the printed circuit board with respect to said shell.

9. A shell according to claim 1, further comprising:
d) means for locating said shell in a predetermined position on a chassis for electrical circuitry.

10. A shell according to claim 9, wherein said locating means includes locating protrusions.

11. A shell for housing a fan, comprising:
a) a first fan compartment;
b) a printed circuit board compartment adjacent said fan compartment;
c) a first baffle extending between said fan compartment and said printed circuit board compartment;
d) said shell being molded of plastic as a unitary member.

12. A shell according to claim 11, further comprising;
e) a second fan compartment adjacent said first compartment;
f) a second baffle dividing said first fan compartment from said second fan compartment.

13. A shell according to claim 11, further comprising:
e) resilient tangs adapted for engaging a fan flange to retain a fan within said first fan compartment.

14. A shell according to claim 13 wherein said first fan compartment is generally rectangular and wherein four said resilient tangs are located adjacent the four corners of said first fan compartment.

15. A shell according to claim 11, wherein said first baffle defines a wiring channel to receive wiring extending between a fan in the first fan compartment and a printed circuit board in said printed circuit board compartment.

16. A shell according to claim 12, wherein said first baffle defines two wiring channels, the first said channel to receive wiring extending between a first fan in the first fan compartment and a printed circuit board in said printed circuit board compartment the second said channel to receive wiring extending between a second fan in the second fan compartment and the printed circuit board in said printed circuit board compartment.

17. A shell according to claim 16, wherein said second baffle defines a wiring channel to receive wiring extending from the second fan positioned in the second fan compartment to the first fan compartment.

18. A shell according to claim 11, wherein said fan compartment has a grill covering and the edges of said grill are curved to smooth air flow from the fan through the grill covering.

19. A method of making a shell for housing a fan, comprising the step of molding from plastic as a single unitary member a shell having resilient tangs adapted for engaging and snap-coupling a fan to said shell, and said shell defining slots for receiving a printed circuit board therein and said shell having resilient tangs terminating in stopping protrusions for engaging an edge of a printed circuit board to maintain a printed circuit board as positioned within said slots.

20. A fan module comprising:
a) a single-piece shell molded from plastic and having molded therein:
i) means for snap-coupling a fan to the shell;
ii) means for snap-coupling a printed circuit board assembly to the shell;
b) a fan, snap-coupled to said shell;
c) a printed circuit board assembly snap-coupled to the shell.
